(19) United States
(12) Patent Application Publication
(10) Pub. No.: US 2026/0130101 A1
(43) Pub. Date: May 7, 2026

(54) DISPLAY APPARATUS

(71) Applicant: LG Display Co., Ltd., Seoul (KR)

(72) Inventors: Yeonsuk KANG, Paju-si (KR); Kisuk KANG, Paju-si (KR)

(73) Assignee: LG Display Co., Ltd., Seoul (KR)

(21) Appl. No.: 19/335,716

(22) Filed: Sep. 22, 2025

(30) Foreign Application Priority Data
Nov. 1, 2024 (KR) 10-2024-0153201

(51) Int. Cl. H10K 59/80; H10K 59/50

(52) U.S. Cl. CPC H10K 59/8791; H10K 59/50; H10K 59/873

(57) ABSTRACT

According to one or more example embodiments, a display apparatus includes a substrate; a first light-emitting area, a second light-emitting area, and a third light-emitting area for emitting light of different colors; a light-emitting element disposed on the substrate; an encapsulation layer disposed on the light-emitting element; and a light control member disposed on the encapsulation layer between the first light-emitting area, the second light-emitting area, and the third light-emitting area, in which the light control member includes a first light control layer disposed on the encapsulation layer, a first insulating film disposed on the first light control layer, and a second light control layer disposed on the first insulating film.

### CROSS-REFERENCE TO RELATED APPLICATION

The present application claims the benefit of and priority to Korean Patent Application No. 10-2024-0153201, filed Nov. 1, 2024, the entire contents of which are incorporated herein by reference for all purposes.

### BACKGROUND

### 1. Technical Field

The present disclosure relates to a display apparatus.

### 2. Description of Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption than the LCD apparatus because it does not require a separate backlight. In addition, there is an advantage in that the OLED display apparatus can drive at a low voltage, have a fast response time, and especially have the inexpensive manufacturing cost.

Recently, demand for a display apparatus that requires augmented reality (AR), virtual reality (VR), or equivalent ultra-high resolution using such an OLED display apparatus is increasing.

The description of related art should not be considered prior art merely because it is mentioned in or associated with this section. The description of related art includes information that describes one or more aspects of the subject technology, and the description in this section does not limit the scope of the invention.

### SUMMARY

The inventors of the present disclosure have recognized the problems and needs of the related art, have performed extensive research and experiments, and have developed a new invention. One or more aspects of the present disclosure are directed to an apparatus that substantially obviates one or more problems due to limitations and disadvantages of the related art.

In one or more aspects, the present disclosure is directed to providing a display apparatus in which it is possible to suppress or prevent color mixing between adjacent pixels.

In one or more aspects, the present disclosure is also directed to providing a display apparatus in which it is possible to suppress or prevent degradation of uniformity and luminance according to a viewing angle.

In one or more aspects, the present disclosure is also directed to providing a display apparatus in which it is possible to suppress or prevent an abnormal light-emitting phenomenon due to light reflection of a black matrix.

Aspects of the present disclosure are not limited to the above-described aspects, and other technical aspects may be inferred from the following example embodiments.

According to one or more example embodiments of the present disclosure, there is provided a display apparatus including: a substrate; a first light-emitting area, a second light-emitting area, and a third light-emitting area for emitting light of different colors; a light-emitting element disposed on the substrate; an encapsulation layer disposed on the light-emitting element; and a light control member disposed on the encapsulation layer between the first light-emitting area, the second light-emitting area, and the third light-emitting area, in which the light control member includes a first light control layer disposed on the encapsulation layer, a first insulating film disposed on the first light control layer, and a second light control layer disposed on the first insulating film.

According to one or more example embodiments of the present disclosure, there is provided a display apparatus including a substrate, a light-emitting area for emitting light of different colors and a non-light-emitting area disposed around the light-emitting area, a light-emitting element disposed on the substrate, an encapsulation layer disposed on the light-emitting element, a first light control layer disposed on the encapsulation layer in the non-light-emitting area, and a color filter layer disposed on the encapsulation layer and covering the first light control layer, in which the first light control layer is formed of TiN.

Additional description of one or more example embodiments are included in the detailed description and accompanying drawings.

According to one or more example embodiments of the present disclosure, it is possible to suppress or prevent light color mixing between adjacent pixels.

According to one or more example embodiments of the present disclosure, it is possible to suppress or prevent degradation of uniformity and luminance according to a viewing angle.

According to one or more example embodiments of the present disclosure, it is possible to suppress or prevent an abnormal light-emitting phenomenon due to light reflection of the black matrix.

According to one or more example embodiments of the present disclosure, it is possible to suppress or prevent color mixing, degradation of a color viewing angle, degradation of luminance, and an abnormal light-emitting phenomenon, thereby enabling operational defect prevention, luminance improvement, and the like of the display apparatus and reducing power consumption.

However, effects obtainable from the present disclosure are not limited to the above-described effects, and other effects that are not mentioned will be clearly understood by those skilled in the art to which the present disclosure pertains in view of the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a plan view of a display apparatus according to an example embodiment.

FIG. 2 is an example enlarged view of a periphery of a sub-pixel in FIG. 1.

FIG. 3 is an example cross-sectional view along line A-A′ in FIG. 2.

FIG. 4 is an example cross-sectional view along line B-B′ in FIG. 2.

FIG. 5 is an example cross-sectional view along line C-C′ in FIG. 2.

FIG. 6 is an example enlarged view of area Q1 in FIG. 3.

FIG. 7 is an example schematic view illustrating a path of light around a light control member.

FIG. 8 is an example plan view of a periphery of a sub-pixel according to another example embodiment.

FIG. 9 is an example cross-sectional view of a periphery of a light control member according to still another example embodiment.

FIG. 10 is an example cross-sectional view of a periphery of a light control member according to yet another example embodiment.

FIG. 11 is an example cross-sectional view of a periphery of a light control member according to yet another example embodiment.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, or (iii) the element, or all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

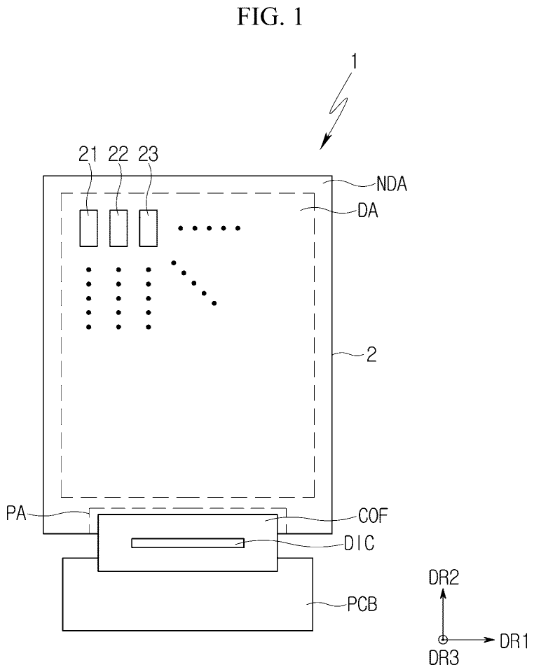

FIG. 1 is a plan view of a display apparatus according to an example embodiment.

Referring to FIG. 1, a display apparatus 1 may include a display area DA and a non-display area NDA. The display area DA may be an area in which light is emitted to the outside to display a screen. The non-display area NDA may be an area in which light is not emitted to the outside so as not to display a screen.

The non-display area NDA may be located around the display area DA. The non-display area NDA may surround the display area DA, but the embodiments of the present disclosure are not limited thereto. A bezel area of the display apparatus 1 may be defined by the non-display area NDA, but the embodiments of the present disclosure are not limited thereto.

The display apparatus 1 may include a plurality of sub-pixels 21, 22, and 23. The plurality of sub-pixels 21, 22, and 23 may be disposed in the display area DA.

The plurality of sub-pixels 21, 22, and 23 may be formed on a substrate 2. The plurality of sub-pixels 21, 22, and 23 may form one pixel. The plurality of pixels may be formed on the substrate 2.

The plurality of sub-pixels 21, 22, and 23 include a first sub-pixel 21, a second sub-pixel 22, and a third sub-pixel 23. Since the first sub-pixel 21, the second sub-pixel 22, and the third sub-pixel 23 may be sequentially arranged, the second sub-pixel 22 may be disposed adjacent to one side, for example, the left side of the first sub-pixel 21, and the third sub-pixel 23 may be disposed adjacent to one side, for example, the left side of the second sub-pixel 22.

In one or more aspects, throughout the present disclosure, when two sub-pixels are disposed adjacent to each other, it should be construed to mean that no other sub-pixels are disposed between the two sub-pixels.

The first sub-pixel 21 may be provided to emit red (R) light, the second sub-pixel 22 may be provided to emit blue (B) light, and the third sub-pixel 23 may be provided to emit green (G) light, but the embodiments of the present disclosure are not limited thereto.

FIG. 1 illustrates an example in which a pixel includes only three sub-pixels 21, 22, and 23, but the embodiments of the present disclosure are not limited thereto, and the pixel may include four sub-pixels. When the pixel includes four sub-pixels, the pixel may further include a fourth sub-pixel provided to emit white (W) light.

Each of the first to third sub-pixels 21, 22, and 23 may be provided to have the same size. For example, each of the first to third sub-pixels 21, 22, and 23 may be provided to have the same width and the same height.

Here, the width may refer to a horizontal direction (a first direction DR1) based on FIG. 1, and the height may refer to a direction (a second direction DR2) perpendicular to the width based on FIG. 1, but the embodiments of the present disclosure are not limited thereto. The first direction DR1 may intersect the second direction DR2, and a third direction DR3 may intersect the first direction DR1 and the second direction DR2. A third direction DR3 may refer to a thickness direction of the display apparatus 1, but is not limited thereto.

The first direction DR1, the second direction DR2, and the third direction DR3 should be understood as relative directions and are not limited to embodiments of the present disclosure.

The display apparatus 1 may further include a pad area PA. The pad area PA may be disposed in the non-display area NDA. In FIG. 1, the pad area PA is illustrated as being disposed under the display area DA (at one side of the display area DA in the second direction DR2), but is not limited thereto. The pad area PA may be disposed at the other side of the display area DA in the second direction DR2 or disposed at one side and/or the other side of the display area DA in the first direction DR1.

The display apparatus 1 may further include a printed circuit board PCB, a flexible film COF, and a drive integrated circuit (IC) DIC.

The printed circuit board PCB may be connected to the sub-pixels 21, 22, and 23 and the like on the substrate 2 through a flexible film COF. The printed circuit board PCB may be electrically connected to the flexible film COF. Although not illustrated, the printed circuit board PCB and the flexible film COF may be electrically connected through a plurality of pads.

The printed circuit board PCB may have various types of components for supplying various signals, such as a driving signal, a data signal, and the like, to the drive IC DIC.

FIG. 1 illustrates a single printed circuit board PCB, but the embodiments of the present disclosure are not limited thereto, and the number of printed circuit boards PCB may vary according to a design.

At least a part of the flexible film COF may be disposed in the non-display area NDA. The flexible film COF may be electrically connected to the pad area PA. The flexible film COF may supply driving signals, power voltages, data voltages, and the like to the plurality of sub-pixels 21, 22, and 23 of the display area DA and driving circuits.

The flexible film COF may be a flexible insulating film. The flexible film COF may include, for example, polycarbonate, polyethylene terephthalate, polyimide, polyamide, polyester, polyacrylate, polymethyl methacrylate, etc., but is not limited thereto.

The drive IC DIC may be mounted on the flexible film COF. The drive IC DIC may be disposed by a method of a chip on glass, a chip on film, a tape carrier package, etc. according to a mounting method. In the present disclosure, the drive IC DIC is described as being mounted on the flexible film COF by the chip on film method, but is not limited thereto.

The drive IC DIC may drive the display apparatus 1. The drive IC DIC may process data signals for displaying a video, various driving signals for processing the data signals, and the like. The drive IC DIC may include a gate driver IC, a data driver IC, etc.

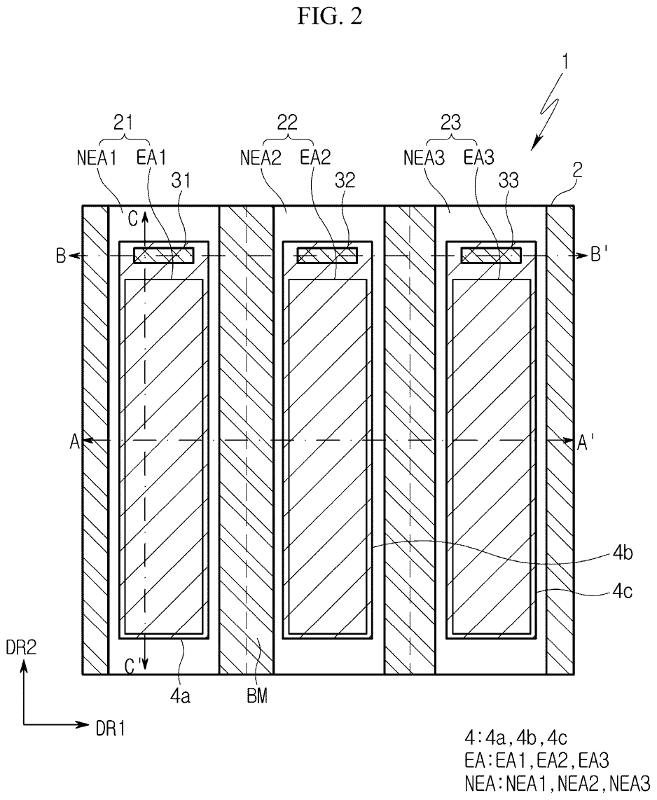

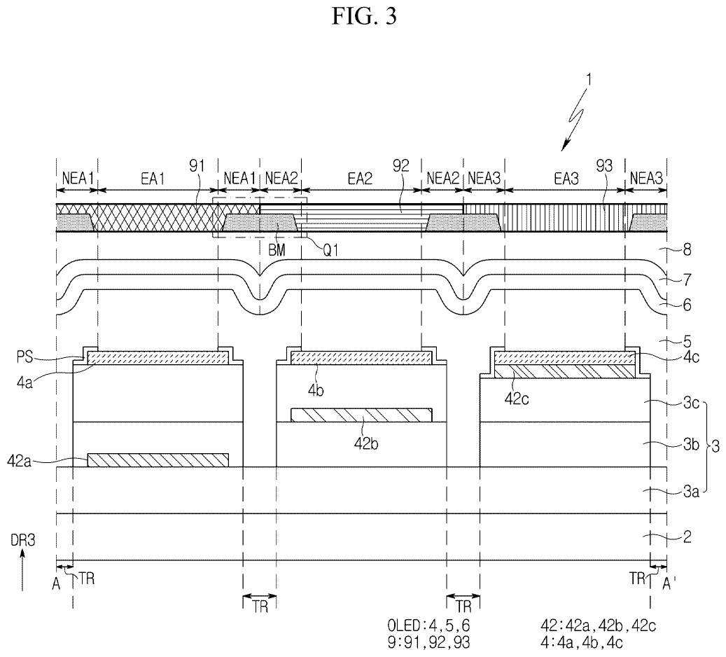

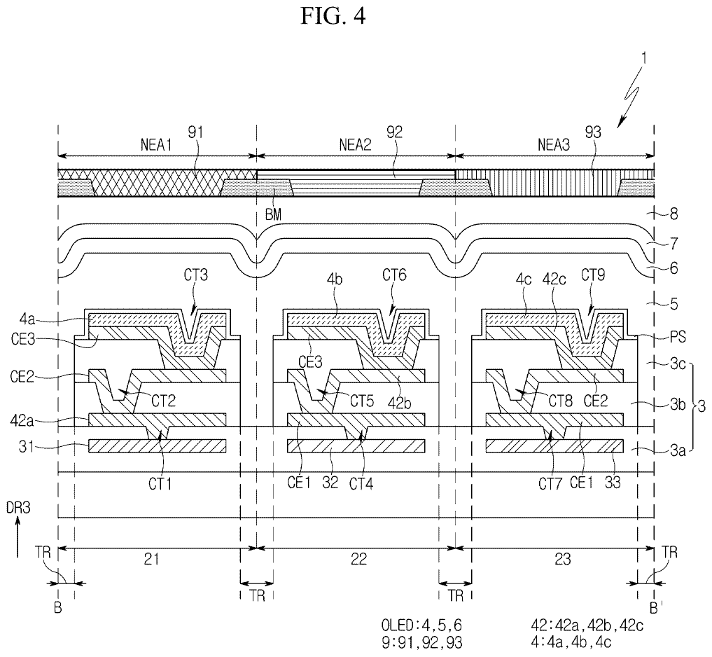

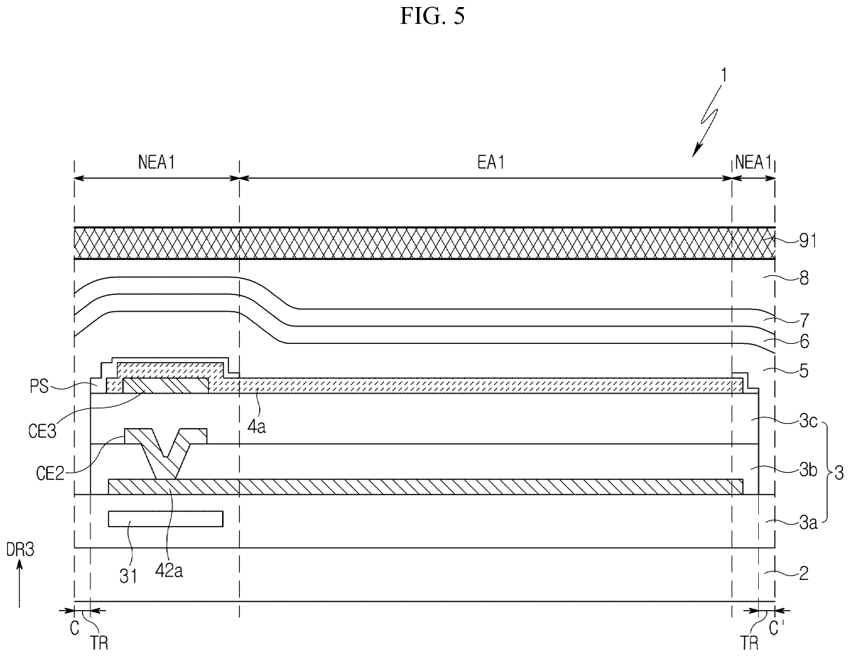

FIG. 2 is an example enlarged view of a periphery of a sub-pixel in FIG. 1. FIG. 3 is an example cross-sectional view along line A-A′ in FIG. 2. FIG. 4 is an example cross-sectional view along line B-B′ in FIG. 2. FIG. 5 is an example cross-sectional view along line C-C′ in FIG. 2.

Referring to FIGS. 2 to 5, the display apparatus 1 according to an example embodiment may include a substrate 2, an insulating layer 3 (3a, 3b, and 3c), an anode electrode layer 4 (4a, 4b, and 4c), a bank layer PS (or a bank), a common light-emitting layer 5, a cathode electrode 6, a capping layer 7, an encapsulation layer 8, and a color filter layer 9.

The sub-pixels 21, 22, and 23 may include light-emitting areas EA1, EA2, and EA3 and non-light-emitting areas NEA1, NEA2, and NEA3, respectively. The first sub-pixel 21 may include a first light-emitting area EA1 and a first non-light-emitting area NEA1 around the first light-emitting area EA1, the second sub-pixel 22 may include a second light-emitting area EA2 and a second non-light-emitting area NEA2 around the second light-emitting area EA2, and the third sub-pixel 23 may include a third light-emitting area EA3 and a third non-light-emitting area NEA3 around the third light-emitting area EA3.

The display apparatus 1 may further include transistors 31, 32, and 33. The transistors 31, 32, and 33 may be disposed in the non-light-emitting areas NEA1, NEA2, and NEA3 of the sub-pixels 21, 22, and 23, respectively. For example, the transistors 31, 32, and 33 may be located at sides of reflective electrodes 42a, 42b, and 42c in the second direction DR2, but are not limited thereto.

The transistors 31, 32, and 33 may be disposed in the light-emitting areas EA1, EA2, and EA3 and disposed under the reflective electrodes 42a, 42b, and 42c, and in this case, the transistors 31, 32, and 33 cannot be visible externally.

The anode electrode layers 4a, 4b, and 4c may be electrically connected to the corresponding transistors 31, 32, and 33 through connection electrodes CE (CE1, CE2, and CE3), the reflective electrodes 42a, 42b, and 42c, and contact holes CT (CT1 to CT9) that are disposed in the sub-pixels 21, 22, and 23, respectively.

Referring to FIGS. 2 to 5, a trench TR may be disposed between the sub-pixels 21, 22, and 23 or between light-emitting areas EA1, EA2, and EA3 of the sub-pixels 21, 22, and 23. The trench TR may be defined by a second insulating layer 3b and a third insulating layer 3c. The trench TR may be formed in a groove or recess shape in which the second insulating layer 3b and the third insulating layer 3c are removed to expose a first insulating layer 3a. The trench TR may be defined by a side surface of the second insulating layer 3b, a side surface of the third insulating layer 3c, and an upper surface of the first insulating layer 3a, but is not limited thereto. The trench TR may be disposed at or in a trench area between the sub-pixels 21, 22, and 23 or between light-emitting areas EA1, EA2, and EA3 of the sub-pixels 21, 22, and 23.

The trench TR may extend in the first direction DR1 and the second direction DR2. The trench TR extending in the first direction DR1 may intersect the trench TR extending in the second direction DR2. For example, a respective portion of the trench TR may surround each light-emitting area (e.g., each of areas EA1, EA2, and EA3) in both of the first direction DR1 and the second direction DR2.

Since the trench TR is disposed between the sub-pixels 21, 22, and 23, even when the common light-emitting layer 5 and the cathode electrode 6 are disposed entirely in the sub-pixels 21, 22, and 23 without distinction, it is possible to prevent a leakage current between the sub-pixels 21, 22, and 23 and prevent a short circuit between a charge generation layer of the common light-emitting layer 5 and the cathode electrode 6, thereby preventing light color mixing. In one or more examples, the trench TR may be utilized not only in connection with FIGS. 2 to 5 but also in connection with other figures disclosed herein, such as FIGS. 1 and 6 to 11.

The substrate 2 may be a plastic film, a glass substrate, or a semiconductor substrate, such as silicon.

The substrate 2 may be formed of a transparent material or an opaque material. The first sub-pixel 21, the second sub-pixel 22, and the third sub-pixel 23 are provided on the substrate 2. The first sub-pixel 21 may be provided to emit red (R) light, the second sub-pixel 22 may be provided to emit blue (B) light, and the third sub-pixel 23 may be provided to emit green (G) light.

Since the display apparatus 1 according to an example embodiment is configured in a so-called top emission type in which emitted light is emitted upward, both a transparent material and an opaque material may be used as a material of the substrate 2. Color filters 91, 92, and 93 may be respectively provided above the first to third sub-pixels 21, 22, and 23 from which light is emitted to transmit light of the above colors. Each of the color filters 91, 92, and 93 may transmit light of a different color.

The display area DA, the non-display area NDA, the pad area PA, the light-emitting area EA (EA1, EA2, and EA3), and the non-light-emitting area NEA (NEA1, NEA2, and NEA3) may be defined on the substrate 2. That is, the substrate 2 may include the display area DA, the non-display area NDA, the pad area PA, the light-emitting area EA, and the non-light-emitting area NEA.

The insulating layer 3 is formed on the substrate 2. The insulating layer 3 may include the plurality of insulating layers 3a, 3b, and 3c. Hereinafter, the insulating layer 3 is described as including the first to third insulating layers 3a, 3b, and 3c, but is not limited thereto, and an additional insulating layer may be further disposed between the first to third insulating layers 3a, 3b, and 3c.

The first insulating layer 3a is disposed on the substrate 2, and circuit elements including the plurality of thin film transistors 31, 32, and 33, various signal lines, capacitors, and the like are provided in the first insulating layer 3a of each sub-pixel 21, 22, or 23. The signal lines may include a gate line, a data line, a power line, and a reference line, and the thin film transistors 31, 32, and 33 may include a switching thin film transistor, a driving thin film transistor, and a sensing thin film transistor. Each of the sub-pixels 21, 22, and 23 is defined by an intersection structure of gate lines and data lines.

The switching thin film transistor serves to supply the driving thin film transistor with a data voltage switched according to a gate signal supplied to the gate line and supplied from the data line.

The driving thin film transistor is switched according to the data voltage supplied from the switching thin film transistor to generate a data current from a power source supplied from the power line and supply the data current to the anode electrode layer 4.

The sensing thin film transistor serves to detect a threshold voltage deviation of the driving thin film transistor, which causes the degradation of image quality, and supplies the current of the driving thin film transistor to the reference line in response to a sensing control signal supplied from the gate line or a separate sensing line.

The capacitor serves to maintain the data voltage supplied to the driving thin film transistor for one frame and is connected to each of a gate terminal and a source terminal of the driving thin film transistor.

A first transistor 31, a second transistor 32, and a third transistor 33 are respectively disposed in the sub-pixels 21, 22, and 23 in the first insulating layer 3a. The first transistor 31 may be connected to a first anode electrode 4a disposed on the first sub-pixel 21 to apply a driving voltage for emitting light of a color corresponding to the first sub-pixel 21.

The second transistor 32 may be connected to a second anode electrode 4b disposed on the second sub-pixel 22 to apply a driving voltage for emitting light of a color corresponding to the second sub-pixel 22.

The third transistor 33 may be connected to a third anode electrode 4c disposed on the third sub-pixel 23 to apply a driving voltage for emitting light of a color corresponding to the third sub-pixel 23.

When receiving the gate signal from the gate line using each of the transistors 31, 32, and 33, each of the first sub-pixel 21, the second sub-pixel 22, and the third sub-pixel 23 supplies a predetermined current to the light-emitting layer according to the data voltage of the data line. Accordingly, the light-emitting layer of each of the first sub-pixel 21, the second sub-pixel 22, and the third sub-pixel 23 may emit light with a predetermined brightness according to the predetermined current.

The first insulating layer 3a may protect the transistors 31, 32, and 33. The first insulating layer 3a may be formed of an inorganic insulation material, but is not limited thereto and may be formed of an organic insulation material. The transistors 31, 32, and 33 may be located in the first insulating layer 3a. For example, the first insulating layer 3a may be formed of an inorganic material, such as silicon nitride (SiNₓ), silicon oxide (SiOₓ), aluminum oxide (Al₂O₃), or the like, but the embodiments of the present disclosure are not limited thereto.

The second insulating layer 3b may be disposed on the first insulating layer 3a. For example, the second insulating layer 3b may be formed of an inorganic material, such as silicon nitride (SiNₓ), silicon oxide (SiOₓ), aluminum oxide (Al₂O₃), or the like, but the embodiments of the present disclosure are not limited thereto.

The third insulating layer 3c may be disposed on the second insulating layer 3b. For example, the third insulating layer 3c may be formed of an inorganic material, such as silicon nitride (SiNₓ), silicon oxide (SiOₓ), aluminum oxide (Al₂O₃), or the like, but the embodiments of the present disclosure are not limited thereto.

However, the embodiments of the present disclosure are not limited thereto, and an additional insulating layer may be further disposed between the insulating layers 3a, 3b, and 3c.

The anode electrode layer 4 is patterned for each sub-pixel 21, 22, or 23. For example, one anode electrode layer 4 may be formed in the first sub-pixel 21, another anode electrode layer 4 may be formed in the second sub-pixel 22, and still another anode electrode layer 4 may be formed in the third sub-pixel 23.

That is, the anode electrode layer 4 may include the first anode electrode 4a, the second anode electrode 4b, and the third anode electrode 4c separately. The first anode electrode 4a, the second anode electrode 4b, and the third anode electrode 4c may be disposed in the sub-pixel 21, 22, and 23, respectively. The anode electrode layer 4 may serve as an anode of the display apparatus 1.

The display apparatus 1 may further include the reflective electrode 42 (42a, 42b, and 42c) having different surface heights. By providing the reflective electrode 42 (42a, 42b, and 42c) having different surface heights, it is possible to further increase light extraction efficiency using a micro-cavity characteristic.

In one or more aspects, the micro-cavity characteristic refers to a characteristic that, when a distance between the reflective electrode 42 and the cathode electrode 6 is an integer multiple of a half wavelength (λ/2) of light emitted from a sub-pixel, constructive interference occurs to amplify the light, and when a reflection and re-reflection process is repeated between the reflective electrode 42 and the cathode electrode 6, a degree of amplified light continuously increases, thereby increasing the external extraction efficiency of light.

The reflective electrode 42 may include a first reflective electrode 42a disposed in the first sub-pixel 21, a second reflective electrode 42b disposed in the second sub-pixel 22, and a third reflective electrode 42c disposed in the third sub-pixel 23.

In the first sub-pixel 21, the first insulating layer 3a, the first transistor 31 disposed in the first insulating layer 3a, a first reflective electrode 42a disposed on the first insulating layer 3a, the second insulating layer 3b disposed on the first reflective electrode 42a, a second connection electrode CE2 disposed on the second insulating layer 3b, the third insulating layer 3c disposed on the second connection electrode CE2, a third connection electrode CE3 disposed on the third insulating layer 3c, the first anode electrode 4a disposed on the third connection electrode CE3, and the bank layer PS disposed on the first anode electrode 4a may be disposed sequentially on the substrate 2.

In the first sub-pixel 21, the first reflective electrode 42a may be patterned and disposed across the first light-emitting area EA1 and the first non-light-emitting area NEA1. In the first sub-pixel 21, the second connection electrode CE2 and the third connection electrode CE3 may be patterned and disposed in the first non-light-emitting area NEA1.

In the second sub-pixel 22, the first insulating layer 3a, the second transistor 32 disposed in the first insulating layer 3a, the first connection electrode CE1 disposed on the first insulating layer 3a, the second insulating layer 3b disposed on the first connection electrode CE1, a second reflective electrode 42b disposed on the second insulating layer 3b, the third insulating layer 3c disposed on the second reflective electrode 42b, the third connection electrode CE3 disposed on the third insulating layer 3c, the second anode electrode 4b disposed on the third connection electrode CE3, and the bank layer PS disposed on the second anode electrode 4b may be disposed sequentially on the substrate 2.

In the second sub-pixel 22, the second reflective electrode 42b may be patterned and disposed across the second light-emitting area EA2 and the second non-light-emitting area NEA2. In the second sub-pixel 22, the first connection electrode CE1 and the third connection electrode CE3 may be patterned and disposed in the second non-light-emitting area NEA2.

In the third sub-pixel 23, the first insulating layer 3a, the third transistor 33 disposed in the first insulating layer 3a, the first connection electrode CE1 disposed on the first insulating layer 3a, the second insulating layer 3b disposed on the first connection electrode CE1, the second connection electrode CE2 disposed on the second insulating layer 3b, the third insulating layer 3c disposed on the second connection electrode CE2, a third reflective electrode 42c disposed on the third insulating layer 3c, the third anode electrode 4c disposed on the third reflective electrode 42c, and the bank layer PS disposed on the third anode electrode 4c may be disposed sequentially on the substrate 2.

In the third sub-pixel 23, the third reflective electrode 42c may be patterned and disposed across the third light-emitting area EA3 and the third non-light-emitting area NEA3. In the third sub-pixel 23, the first connection electrode CE1 and the second connection electrode CE2 may be patterned and disposed in the third non-light-emitting area NEA3.

The first reflective electrode 42a disposed in the first sub-pixel 21 and the first connection electrode CE1 disposed in the second sub-pixel 22 and the third sub-pixel 23 may each be disposed separately, but may be formed on the same layer, may include the same material, may be formed by the same process, and may be formed at the same time, but are not limited thereto.

The second reflective electrode 42b disposed in the second sub-pixel 22 and the second connection electrode CE2 disposed in the first sub-pixel 21 and the third sub-pixel 23 may each be disposed separately, but may be formed on the same layer, may include the same material, and may be formed by the same process, and may be formed at the same time, but are not limited thereto.

The third reflective electrode 42c disposed in the third sub-pixel 23 and the third connection electrode CE3 disposed in the first sub-pixel 21 and the second sub-pixel 22 may each be disposed separately, but may be formed on the same layer, may include the same material, and may be formed by the same process, and may be formed at the same time, but are not limited thereto.

In the non-light-emitting areas NEA1, NEA2, and NEA3, the contact hole CT (CT1 to CT9) may be defined by passing through the first to third insulating layers 3a to 3c in the thickness direction (the third direction DR3), and in the sub-pixels 21, 22, and 23, the contact holes CT (CT1 to CT9) may electrically connect the transistors 31, 32, and 33 to the anode electrode layer 4 (4a, 4b, and 4c), respectively.

A first contact hole CT1 may be defined by the first insulating layer 3a in the first light-emitting area EA1. The first contact hole CT1 may pass through the first insulating layer 3a in the thickness direction (the third direction DR3) to expose the first transistor 31. In the first light-emitting area EA1, the first reflective electrode 42a may be in contact with the first transistor 31 through the first contact hole CT1.

A second contact hole CT2 may be defined by the second insulating layer 3b in the first light-emitting area EA1. The second contact hole CT2 may pass through the second insulating layer 3b in the thickness direction (the third direction DR3) to expose the first reflective electrode 42a. In the first light-emitting area EA1, the second connection electrode CE2 may be in contact with the first reflective electrode 42a through the second contact hole CT2.

A third contact hole CT3 may be defined by the third insulating layer 3c in the first light-emitting area EA1. The third contact hole CT3 may pass through the third insulating layer 3c in the thickness direction (the third direction DR3) to expose the second connection electrode CE2. In the first light-emitting area EA1, the third connection electrode CE3 may be in contact with the second connection electrode CE2 through the third contact hole CT3.

A fourth contact hole CT4 may be defined by the first insulating layer 3a in the second light-emitting area EA2. The fourth contact hole CT4 may pass through the first insulating layer 3a in the thickness direction (the third direction DR3) to expose the second transistor 32. In the second light-emitting area EA2, the first connection electrode CE1 may be in contact with the second transistor 32 through the fourth contact hole CT4.

A fifth contact hole CT5 may be defined by the second insulating layer 3b in the second light-emitting area EA2. The fifth contact hole CT5 may pass through the second insulating layer 3b in the thickness direction (the third direction DR3) to expose the first connection electrode CE1. In the second light-emitting area EA2, the second reflective electrode 42b may be in contact with the first connection electrode CE1 through the fifth contact hole CT5.

A sixth contact hole CT6 may be defined by the third insulating layer 3c in the second light-emitting area EA2. The sixth contact hole CT6 may pass through the third insulating layer 3c in the thickness direction (the third direction DR3) to expose the second reflective electrode 42b. In the second light-emitting area EA2, the third connection electrode CE3 may be in contact with the second reflective electrode 42b through the sixth contact hole CT6.

A seventh contact hole CT7 may be defined by the first insulating layer 3a in the third light-emitting area EA3. The seventh contact hole CT7 may pass through the first insulating layer 3a in the thickness direction (the third direction DR3) to expose the third transistor 33. In the third light-emitting area EA3, the first connection electrode CE1 may be in contact with the third transistor 33 through the seventh contact hole CT7.

An eighth contact hole CT8 may be defined by the second insulating layer 3b in the third light-emitting area EA3. The eighth contact hole CT8 may pass through the second insulating layer 3b in the thickness direction (the third direction DR3) to expose the first connection electrode CE1. In the third light-emitting area EA3, the second connection electrode CE2 may be in contact with the first connection electrode CE1 through the eighth contact hole CT8.

A ninth contact hole CT9 may be defined by the third insulating layer 3c in the third light-emitting area EA3. The ninth contact hole CT9 may pass through the third insulating layer 3c in the thickness direction (the third direction DR3) to expose the second connection electrode CE2. In the third light-emitting area EA3, the third reflective electrode 42c may be in contact with the second connection electrode CE2 through the ninth contact hole CT9.

As described above, the transistors 31, 32, and 33, the connection electrodes CE1, CE2, and CE3, and the reflective electrodes 42a, 42b, and 42c have been described as being in direct contact with one another through the contact holes CT (CT1 to CT9), but the embodiments of the present disclosure are not limited thereto. For example, each contact hole CT (CT1 to CT9) may be filled with a separate contact layer (not illustrated), and the transistors 31, 32, and 33, the connection electrodes CE1, CE2, and CE3, and the reflective electrodes 42a, 42b, and 42c may be electrically connected by contact layers filling the contact holes CT (CT1 to CT9). Here, the contact layer (not illustrated) may be formed of tungsten, etc.

The reflective electrode 42 (42a, 42b, and 42c) may reflect light, which is emitted toward the reflective electrode 42 among light emitted from the common light-emitting layer 5 of the sub-pixel 21, 22, and 23, toward the cathode electrode 6 or the encapsulation layer 8. In addition, the reflective electrode 42 is formed to implement the micro-cavity characteristic through reflection and re-reflection with the cathode electrode 6. To this end, the reflective electrode 42 may include a reflective material for reflecting light. For example, the reflective material may be a metal, but is not limited thereto, and may be other materials as long as it may reflect light. For example, the reflective material may include titanium (Ti)/aluminum (Al), but is not limited thereto.

The display apparatus 1 according to an example embodiment may be provided in the top emission type, and to this end, the reflective electrode 42 may be provided to reflect the light emitted from the common light-emitting layer 5 upward.

Since the reflective electrode 42 is disposed at a relatively lower location than the common light-emitting layer 5 for emitting light, the reflective electrode 42 may reflect the light emitted from the common light-emitting layer 5 upward. Here, upward may refer to a direction in which a user may perceive light, for example, a side to which the encapsulation layer 8 or the color filter layer 9 is disposed. Accordingly, it is possible to further increase the light efficiency of the first sub-pixel 21, the second sub-pixel 22, and the third sub-pixel 23 compared to a case in which there is no reflective electrode 42, and the user can perceive an image with high brightness, that is, clear image, through the increased light efficiency. That is, the user can perceive a clear image.

As described above, the display apparatus 1 may have the reflective electrode 42, thereby further increasing the light extraction efficiency using the micro-cavity characteristic. The reflective electrode 42 may include the first reflective electrode 42a, the second reflective electrode 42b, and the third reflective electrode 42c.

A distance between the first reflective electrode 42a and the anode electrode layer 4 or 4a may be larger than a distance between the second reflective electrode 42b and the anode electrode layer 4 or 4b. A distance between the second reflective electrode 42b and the anode electrode layer 4 or 4b may be larger than a distance between the third reflective electrode 42c and the anode electrode layer 4 or 4c.

The cathode electrode 6 in the light-emitting area EA1, EA2, and EA3 of the sub-pixels 21, 22, and 23 may be located collinearly. Accordingly, a size relationship between the distance between the reflective electrodes 42a, 42b, or 42c and the anode electrode layer 4 (4a, 4b, or 4c) in each sub-pixel 21, 22, or 23 may be the same as a size relationship between the distance between the reflective electrode 42a, 42b, or 42c and the cathode electrode 6.

In an example, a distance between an upper surface of the first reflective electrode 42a and an upper surface of cathode electrode 6 may be greater than a distance between an upper surface of the second reflective electrode 42b and the upper surface of the cathode electrode 6. A distance between the upper surface of the second reflective electrode 42b and the upper surface of cathode electrode 6 may be greater than a distance between an upper surface of the third reflective electrode 42c and the upper surface of the cathode electrode 6. Similar distance relationships are present between the reflective electrodes 42a, 42b, and 42c and other elements (e.g., 4, 7, 8 or 9) disposed above them, respectively.

In one or more aspects, the reflective electrodes 42a, 42b, and 42c are formed with varying separation distances (or resonance distances) from the cathode electrode 6 to enhance the light extraction efficiency of different colors through reflection and re-reflection between the reflective electrodes 42a, 42b, and 42c and the cathode electrode 6 according to the separation distances. Accordingly, it is possible to increase the light extraction efficiency of red light in the first sub-pixel 21, increase the light extraction efficiency of green light in the second sub-pixel 22, and increase the light extraction efficiency of blue light in the third sub-pixel 23.

The connection electrodes CE1, CE2, and CE3 may be disposed in the light-emitting areas EA1, EA2, and EA3 of the sub-pixels 21, 22, and 23. The connection electrodes CE1, CE2, and CE3 may be disposed on the same layer as the reflective electrodes 42a, 42b, and 42c and formed through the same process.

The anode electrode layer 4 is disposed on the reflective electrode 42. The anode electrode layer 4 is formed to supply holes to the common light-emitting layer 5. The anode electrode layer 4 may be provided transparently so that light reflected from the reflective electrode 42 may proceed upward. The anode electrode layer 4 may be formed of a transparent material, but is not limited thereto, and a metal material may be formed in the form of a thin film as long as it may transmit light. For example, the anode electrode layer 4 may include titanium nitride (TiN), but is not limited thereto. The anode electrode layer 4 may be formed of a very thin film so that the light reflected from the reflective electrode 42 may proceed upward. For example, the thickness of the anode electrode layer 4 may be about 5 nm or less. For example, the thickness of the anode electrode layer 4 may be about 3 nm or less, but is not limited thereto.

The anode electrode layer 4 may come into direct contact with the reflective electrode 42 and may be electrically connected to the reflective electrode 42 or may be indirectly connected to the reflective electrode 42 through the contact hole CT and electrically connected to the reflective electrode 42. The reflective electrode 42 (42a, 42b, and 42c) may be electrically connected to the first to third transistors 31, 32, and 33, respectively, through respective contact hole CT so that a driving voltage provided by the respective one of the first to third transistors 31, 32, and 33 may be applied to the anode electrode layer 4 (4a, 4b, and 4c), respectively. The anode electrode layer 4 (4a, 4b, and 4c) may supply holes to the common light-emitting layer 5 when the driving voltages are applied from the first to third transistors 31, 32, and 33, respectively. In each sub-pixel 21, 22, or 23, the anode electrode layer 4 may come into direct contact with the third connection electrode CE3 or the third reflective electrode 42c.

The anode electrode layer 4 may be disposed in each of the first to third sub-pixels 21, 22, and 23 to have substantially the same height from an upper surface of the reflective electrode 42, the connection electrode CE, or the insulating layer 3.

The bank layer PS may be disposed on the anode electrode layer 4. The bank layer PS may be formed of an inorganic material, such as silicon nitride (SiNₓ), silicon oxide (SiOₓ), aluminum oxide (Al₂O₃), or the like, but the embodiments of the present disclosure are not limited thereto.

The bank layer PS may serve as a bank that defines light-emitting areas EA1, EA2, and EA3 of the sub-pixels 21, 22, and 23. In the light-emitting areas EA1, EA2, and EA3, the bank layer PS may define the light-emitting areas EA1, EA2, and EA3 by exposing upper surfaces of the anode electrode layers 4 (4a, 4b, and 4c). Each light-emitting area EA1, EA2, or EA3 may be the same as an area of the anode electrode layer 4, which is exposed from the bank layer PS.

On the other hand, in the non-light-emitting areas NEA1, NEA2, and NEA3, the bank layer PS may cover the upper surfaces of the anode electrode layers 4a, 4b, and 4c. The bank layer PS (or the bank) may be disposed on each of the first sub-pixel 21, the second sub-pixel 22, and the third sub-pixel 23.

The bank layer PS is illustrated as being formed of a single layer, but is not limited thereto, and the bank layer PS may be formed of multiple layers. The bank layer PS may be provided to cover an edge of the anode electrode layer 4 (4a, 4b, and 4c) disposed in the first to third sub-pixels 21, 22, and 23, respectively, to distinguish the first sub-pixel 21, the second sub-pixel 22, and the third sub-pixel 23.

The common light-emitting layer 5 is formed on the anode electrode layer 4 and the bank layer PS. The common light-emitting layer 5 may be formed as a common layer across the first to third sub-pixels 21, 22, and 23.

An organic light-emitting element OLED according to an example embodiment may include the anode electrode layer 4 (ANO), the cathode electrode 6 (CAT), and the common light-emitting layer 5 between the anode electrode layer 4 and the cathode electrode 6.

In one or more aspects, the common light-emitting layer 5 may be provided to emit white (W) light. To this end, the common light-emitting layer 5 may include a plurality of stacks for emitting light of different colors. For example, the common light-emitting layer 5 may include a first stack, a second stack, and a charge generation layer CGL provided between the first stack and the second stack.

However, the embodiments of the present disclosure area not limited thereto, and the common light-emitting layer 5 may be provided to emit white light by having a three-stack structure including a blue light-emitting layer, a green light-emitting layer, a red light-emitting layer, and a charge generation layer, but is not limited thereto, and may be formed of multiple layers exceeding three stacks as long as it may emit white light.

The cathode electrode 6 is formed on the common light-emitting layer 5. The cathode electrode 6 may serve as a cathode of the display apparatus 1. Like the common light-emitting layer 5, the cathode electrode 6 is formed in each or all of the sub-pixels 21, 22, and 23 and between the sub-pixels 21, 22, and 23.

In the display apparatus 1 according to an example embodiment, the cathode electrode 6 may be formed as a cathode electrode including a translucent material in order to implement white light with light efficiency in the top emission type. Accordingly, the micro-cavity effect can be obtained for each of the first to third sub-pixels 21, 22, and 23. When the cathode electrode 6 is formed as the cathode electrode including a translucent material, the micro-cavity effect can be obtained as light is reflected and re-reflected repeatedly between the cathode electrode 6 and the reflective electrode 42, thereby increasing light extraction efficiency.

In the case of a top emission type, the cathode electrode 6 may be provided as a first electrode, and in the case of a bottom emission type, the cathode electrode 6 may be provided as an opaque cathode electrode including a reflective material. In the case of the top emission type, the cathode electrode 6 may be formed as a cathode electrode including a translucent material to increase light extraction efficiency using the micro-cavity characteristic. Since the display apparatus 1 increases light extraction efficiency using the micro-cavity characteristic in the top emission type, an example in which the cathode electrode 6 is formed of a translucent material will be described.

Meanwhile, since the cathode electrode 6 is formed on the upper surface of the common light-emitting layer 5, the cathode electrode 6 may be formed along a profile of the common light-emitting layer 5. Since the common light-emitting layer 5 is formed along the profile of the anode electrode layer 4 in the light-emitting area, the cathode electrode 6 may be formed along the profile of the anode electrode layer 4. In addition, the capping layer 7 on the cathode electrode 6 may also be formed along a profile of the cathode electrode 6.

The capping layer 7 may be formed of an inorganic insulation material, but is not limited thereto. The capping layer 7 may be formed of a single layer, but is not limited thereto, and may be formed of multiple layers. The capping layer 7 may be disposed on the cathode electrode 6 to protect the organic light-emitting diode OLED.

The encapsulation layer 8 is formed on the cathode electrode 6 to prevent external moisture from penetrating the common light-emitting layer 5. The encapsulation layer 8 may be formed of an inorganic insulation material or formed in a structure in which an inorganic insulation material and an organic insulation material are alternately stacked, but is not limited thereto.

The color filter layer 9 is formed on the encapsulation layer 8. A color filter layer 9 is provided in each of the first to third sub-pixels 21, 22, and 23 to block a specific color from light emitted from the light-emitting layer of each sub-pixel. The color filter layer 9 may include a first color filter 91 provided in the first sub-pixel 21, a second color filter 92 provided in the second sub-pixel 22, and a third color filter 93 provided in the third sub-pixel 23.

A first color filter 91 may be provided to block light of other colors not including red (R) light. In this case, the first color filter 91 may be provided as a red color filter. The second color filter 92 may be provided to block light of other colors not including green (G) light. In this case, a second color filter 92 may be provided as a green color filter. The third color filter 93 may be provided to block light of other colors not including blue (B) light. In this case, the third color filter 93 may be provided as a blue color filter. However, the embodiments of the present disclosure are not limited thereto.

The first to third color filters 91, 92, and 93 provided in the first to third sub-pixels 21, 22, and 23, respectively, may be provided in the same size as the respective sub-pixels or provided by being reduced or expanded at a predetermined ratio to each sub-pixel.

A light control member BM may be disposed on the same layer as the color filter layer 9. The light control member BM may be disposed on the encapsulation layer 8. The light control member BM may be covered by the color filter layer 9.

The light control member BM may be disposed between the color filters 91, 92, and 93. Specifically, the light control member BM may be disposed at boundaries of different color filters 91, 92, and 93 and peripheries thereof. The light control member BM may be covered by at least two of the different color filters 91, 92, and 93 and may overlap the at least two of the different color filters 91, 92, and 93 in the thickness direction (the third direction DR3).

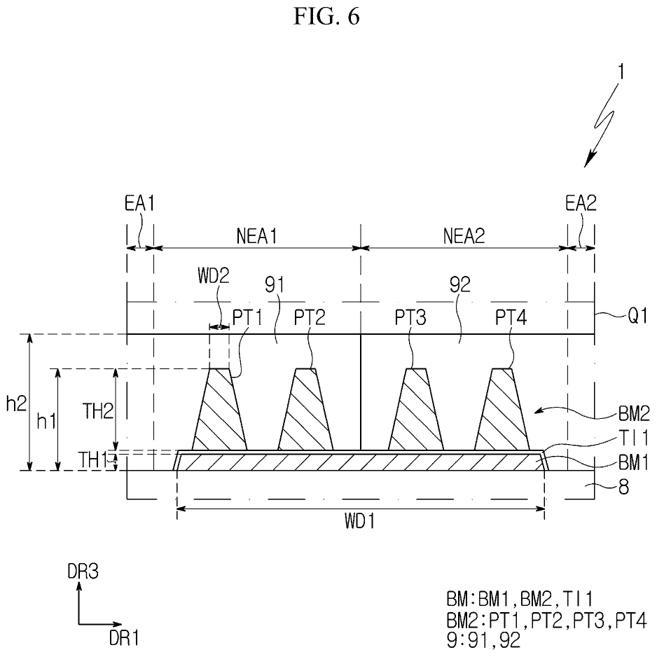

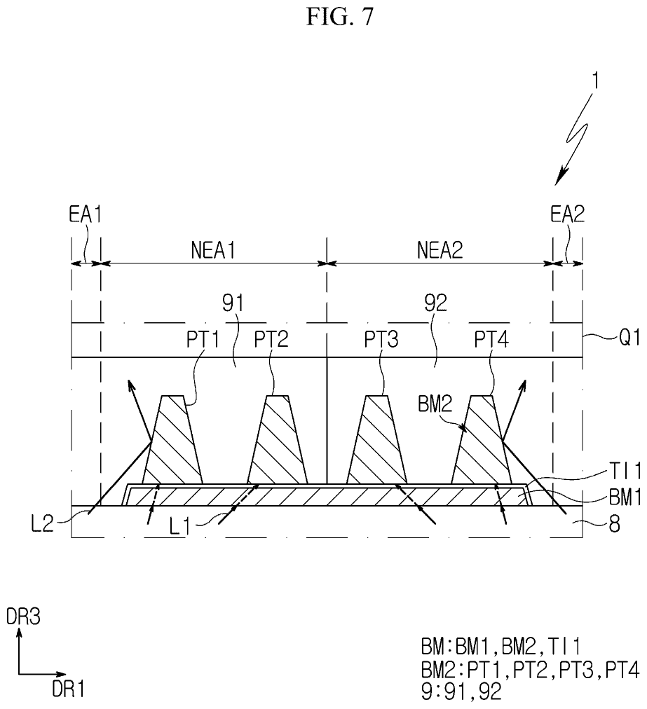

The light control member BM will be described in more detail with reference to FIGS. 6 and 7.

FIG. 6 is an example enlarged view of area Q1 in FIG. 3. FIG. 7 is an example schematic view illustrating a path of light around a light control member.

Referring to FIGS. 2 to 7, the light control member BM may be disposed in the non-light-emitting area NEA.

The light control member BM may be disposed between the sub-pixels 21, 22, and 23 emitting light of different colors. The light control member BM may be disposed around the boundaries of the sub-pixels 21, 22, and 23 emitting light of different colors.

For example, the light control member BM may be disposed around the boundaries of the first sub-pixel 21, the second sub-pixel 22, and the third sub-pixel 23 disposed sequentially in the first direction DR1.

The light control member BM may be disposed between the light-emitting areas EA1, EA2, and EA3 of the sub-pixels 21, 22, and 23 that emit light of different colors.

For example, the light control member BM may be disposed between the first light-emitting area EA1, the second light-emitting area EA2, and the third light-emitting area EA3 that are disposed sequentially in the first direction DR1.

Accordingly, it is possible to suppress or prevent color mixing between the sub-pixels 21, 22, and 23 that emit different colors and furthermore, to suppress or prevent luminance reduction.

The light control member BM may extend in a direction in which the sub-pixels 21, 22, and 23 that emit light of the same color are disposed.

For example, when each of the first sub-pixel 21, the second sub-pixel 22, and the third sub-pixel 23 is disposed repeatedly in the second direction DR2, the light control member BM may extend in the second direction DR2. In this example, the first sub-pixels 21 may be disposed in the second direction DR2 and may emit light of a first color. The second sub-pixels 22 may be disposed in the second direction DR2 and may emit light of a second color. The third sub-pixels 23 may be disposed in the second direction DR2 and may emit light of a third color. The first color is the same for the first sub-pixels 21, the second color is the same for the second sub-pixels 22, and the third color is the same for the third sub-pixels 23. The second color is different from the first color, and the third color is different from the second color.

The light control member BM may be further disposed between the first sub-pixels 21 that emit light of the first color, between the second sub-pixels 22 that emit light of the second color, and between the third sub-pixels 23 that emit light of the third color. In this case, the light control member BM may extend in the first direction DR1.

The light control member BM may be disposed between the color filters 91, 92, and 93. The light control member BM may overlap the color filters 91, 92, and 93 in the thickness direction (the third direction DR3).

The light control member BM may include a first light control layer BM1, a second light control layer BM2 disposed on the first light control layer BM1, and a first insulating film TI1 disposed between the first light control layer BM1 and the second light control layer BM2.

The first light control layer BM1 and the second light control layer BM2 may be formed to be separated.

The first light control layer BM1 and the second light control layer BM2 may include a metallic material. For example, the metallic material may include titanium nitride (TiN). When the first light control layer BM1 and the second light control layer BM2 include titanium nitride (TiN), fine patterning is possible, and thus, even when spaces between the light-emitting areas EA1, EA2, and EA3 are narrow, the light control member BM can be easily disposed.

The first insulating layer TI1 may include a transparent inorganic insulation material. For example, the first insulating film TI1 may include at least one selected from aluminum oxide (AlₓO_{y}), silicon nitride (SiNₓ), etc.

The first insulating film TI1 may be disposed on the first light control layer BM1 to cover both upper surface and side surfaces of the first light control layer BM1, but is not limited thereto.

The first insulating film TI1 may be formed by depositing an inorganic insulation material through an atomic layer deposition (ALD) process. However, the first insulating film TI1 is not limited thereto and may be formed by a chemical vapor deposition (CVD) or physical vapor deposition (PVD) process.

Since the first insulating film TI1 is disposed on the first light control layer BM1, the second light control layer BM2 is disposed on the first insulating film TI1. Accordingly, the second light control layer BM2 can be formed more easily.

The first light control layer BM1 may have a first width WD1 in a direction between the adjacent light-emitting areas EA1, EA2, and EA3 of the adjacent sub-pixels 21, 22, and 23. For example, the first light control layer BM1 may have the first width WD1 in the first direction DR1 between the first light-emitting area EA1 and the second light-emitting area EA2, between the second light-emitting area EA2 and the third light-emitting area EA3, and between the third light-emitting area EA3 and the first light-emitting area EA1.

The first width WD1 of the first light control layer BM1 may range from 400 nanometers (nm) to 800 nm or from 200 nm to 1,000 nm.

The first light control layer BM1 may have a first thickness TH1 in the thickness direction (the third direction DR3). The first thickness TH1 of the first light control layer BM1 may range from 90 nm to 120 nm.

When the first thickness TH1 of the first light control layer BM1 is within the above range, light reflectivity of the first light control layer BM1 formed of TiN may be 30% or less. Here, the light reflectivity of the first light control layer BM1 may refer to light reflectivity of light traveling in the thickness direction (the third direction DR3).

Light L1 emitted from the organic light-emitting element OLED under the light control member BM may be mostly absorbed by the first light control layer BM1. Accordingly, it is possible to minimize the light reflection by the light control member BM and suppress or prevent color mixing and abnormal light-emitting phenomena between adjacent sub-pixels 21, 22, and 23 due to the light reflection by the light control member BM.

The second light control layer BM2 may include a plurality of patterns PT1, PT2, PT3, and PT4. The second light control layer BM2 may include first to fourth patterns PT1, PT2, PT3, and PT4.

The second light control layer BM2 may overlap the first light control layer BM1 in the thickness direction (the third direction DR3). The second light control layer BM2 may overlap the first light control layer BM1 in the thickness direction (the third direction DR3) across the entire area, but is not limited thereto.

FIG. 6 illustrates the second light control layer BM2 formed of four patterns PT1, PT2, PT3, and PT4, but the number of patterns of the second light control layer BM2 is not limited thereto.

The first to fourth patterns PT1, PT2, PT3, and PT4 may be disposed sequentially in the first direction DR1. Each of the first to fourth patterns PT1, PT2, PT3, and PT4 may extend in a direction in which the light control member BM extends. Each of the first to fourth patterns PT1, PT2, PT3, and PT4 may extend in the second direction DR2.

The first to fourth patterns PT1, PT2, PT3, and PT4 may be patterned separately from each other. The first to fourth patterns PT1, PT2, PT3, and PT4 may have substantially the same shape, but are not limited thereto. In an example, each of the first to fourth patterns PT1, PT2, PT3, and PT4 may be an island physically separated from each other and physically not connected to each other. In an example, each island may extend in the second direction DR2 (or along any direction in which the light control member BM extends).

The color filter layer 9 may be disposed between the first to fourth patterns PT1, PT2, PT3, and PT4, but is not limited thereto. The first to fourth patterns PT1, PT2, PT3, and PT4 may be in direct contact with the color filter layer 9, but are not limited thereto.

Each of the first to fourth patterns PT1, PT2, PT3, and PT4 may have a second width WD2 in the direction between adjacent light-emitting areas EA1, EA2, and EA3. For example, each of the first to fourth patterns PT1, PT2, PT3, and PT4 may have the second width WD2 in the first direction DR1 between the first light-emitting area EA1 and the second light-emitting area EA2, between the second light-emitting area EA2 and the third light-emitting area EA3, and between the third light-emitting area EA3 and the first light-emitting area EA1.

The second width WD2 of each of the first to fourth patterns PT1, PT2, PT3, and PT4 may range from 30 nm to 70 nm or from 150 nm to 300 nm.

Here, the second width WD2 may refer to a minimum width of each pattern PT1, PT2, PT3, or PT4 in the first direction DR1. Accordingly, the width of each of the first to fourth patterns PT1, PT2, PT3, and PT4 may range from 30 nm to 70 nm or from 150 nm to 300 nm across the entire area.

In this case, each of the first to fourth patterns PT1, PT2, PT3, and PT4 may have light reflectivity of 35% or more. Here, the light reflectivity may refer to light reflectivity for light traveling in the first direction DR1 and in a direction between the first direction DR1 and the third direction DR3.

By arranging the second light control layer BM2, another part L2 of the light emitted from the organic light-emitting element OLED under the light control member BM may travel in the thickness direction (the third direction DR3) after being reflected by a first pattern PT1 and a fourth pattern PT4 that are disposed at both ends. Accordingly, it is possible to achieve a light condensing effect in each sub-pixel 21, 22, or 23, thereby improving the uniformity of color and luminance according to a viewing angle and suppressing or preventing luminance reduction.

In addition, a second pattern PT2 and a third pattern PT3 that are disposed between the first pattern PT1 and the fourth pattern PT4 can block and/or absorb the part L1 of the light transmitted through the first light control layer BM1 thereunder along with the first pattern PT1 and the fourth pattern PT4.

The plurality of patterns PT1, PT2, PT3, and PT4 may cover 50% or more of an upper surface of the first light control layer BM1.

Since the second light control layer BM2 is formed of the plurality of patterns PT1, PT2, PT3, and PT4, the part L1 of the light transmitted through the first light control layer BM1 can be more easily blocked and/or absorbed.

A first height h1 of the light control member BM may range from 50% to 70% of a second height h2 of the color filter layer 9. Here, the heights h1 and h2 may refer to heights from an upper surface of a layer in which the color filter layer 9 and the light control member BM are disposed.

For example, the first height h1 of the light control member BM may refer to a height from an upper surface of the encapsulation layer 8 to an upper surface of each pattern PT1, PT2, PT3, or PT4 of the second light control layer BM2. The second height h2 of the color filter layer 9 may refer to the height from the upper surface of the encapsulation layer 8 to an upper surface of the color filter layer 9.

Here, the upper surface of each pattern PT1, PT2, PT3, or PT4 of the second light control layer BM2 refers to a surface opposite to a surface (a lower surface) of each pattern PT1, PT2, PT3, or PT4, which faces the first light control layer BM1. The upper surface of the color filter layer 9 refers to a surface opposite to a surface (a lower surface) of the color filter layer 9, which faces the encapsulation layer 8.

When the first height h1 of the light control member BM is lower than 50% of the second height h2 of the color filter layer 9, the light collection effect of the light control member BM can be degraded. When the first height h1 of the light control member BM is higher than 70% of the second height h2 of the color filter layer 9, it may be difficult to arrange the color filter layer 9 to cover the upper surface of the light control member BM.

That is, when the first height h1 of the second light control layer BM2 ranges from 50% to 70% of the second height h2 of the color filter layer 9, it is possible to smoothly secure the light condensing effect and facilitate the formation of the color filter layer 9.

As a result, since the light control member BM is disposed and the light control member BM includes the first light control layer BM1 and the second light control layer BM2, color mixing prevention, the improvement of color and luminance uniformity according to a viewing angle, luminance reduction prevention, and the like can be achieved. Furthermore, it is possible to enable the operation defect prevention, luminance improvement, etc. of the display apparatus 1, thereby reducing power consumption.

Hereinafter, other example embodiments of the present disclosure will be described. For contents that are substantially the same as those described with reference to FIGS. 1 to 7 among components included in other embodiments, the same reference numerals are given, overlapping contents may be omitted or briefly described, and the overlapping contents are applicable to the figures discussed below.

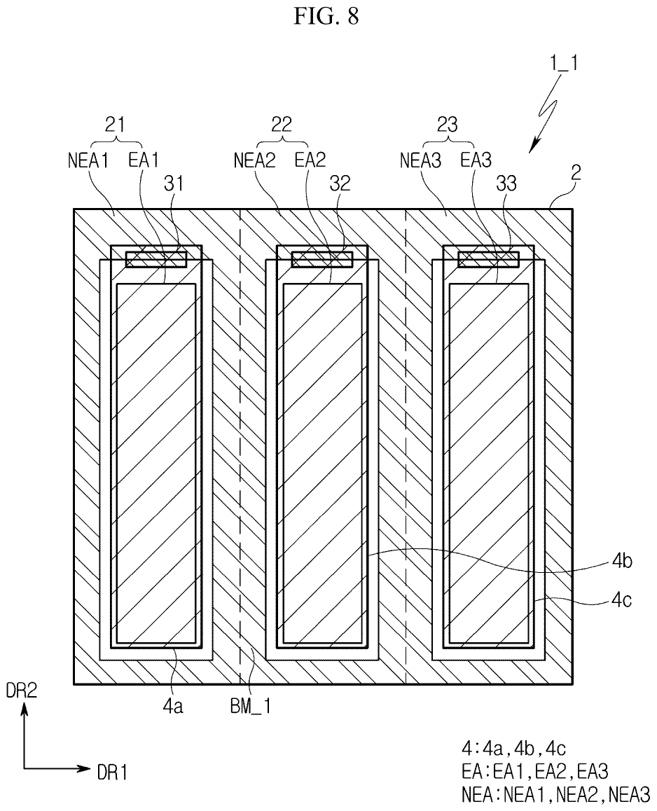

FIG. 8 is an example plan view of a periphery of a sub-pixel according to another example embodiment.

Referring to FIG. 8, a display apparatus 1_1 according to the present example embodiment may include a light control member BM_1, and the light control member BM_1 may be further disposed between the sub-pixels 21, 22, and 23 that emit light of the same color.

The light control member BM_1 may be disposed not only between the sub-pixels 21, 22, and 23 that emit light of different colors and are adjacent to each other in the first direction DR1, but also between the first sub-pixels 21 that emit light of the first color, between the second sub-pixels 22 that emit light of the second color, and between the third sub-pixels 23 that emit light of the third color. The first sub-pixels 21 are adjacent to each other in the second direction DR2. The second sub-pixels 22 are adjacent to each other in the second direction DR2. The third sub-pixels 23 are adjacent to each other in the second direction DR2.

The light control member BM_1 disposed between the first sub-pixels 21, between the second sub-pixels 22, and between the third sub-pixels 23, which are adjacent to each other in the second direction DR2 may extend in the first direction DR1.

Accordingly, it is possible to suppress or prevent interference due to light emission between adjacent sub-pixels 21, 22, and 23 that emit light of the same color, thereby suppressing or preventing luminance reduction and luminance defect.

Even in this case, according to the arrangement of the light control member BM_1, color mixing prevention, improvement of color and luminance uniformity according to a viewing angle, luminance reduction prevention, etc. can be possible.

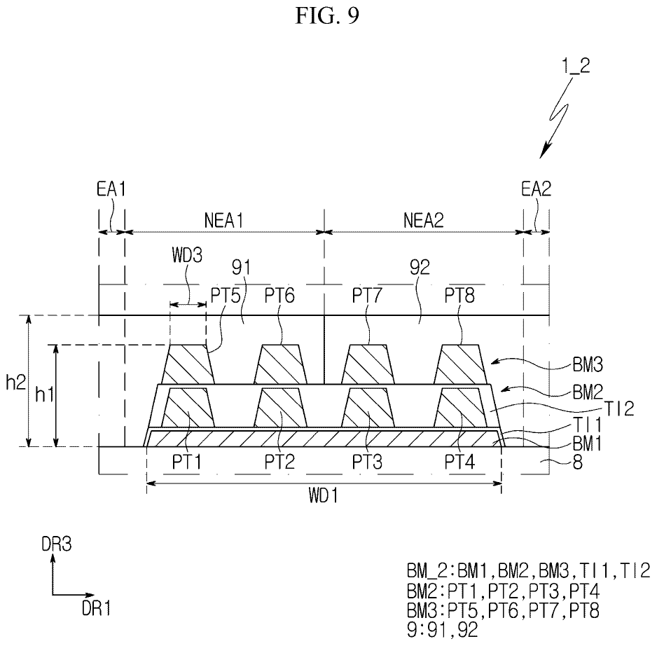

FIG. 9 is an example cross-sectional view of a periphery of a light control member according to still another example embodiment.

Referring to FIG. 9, a display apparatus 1_2 according to the present example embodiment may include a light control member BM_2, and the light control member BM_2 may further include a second insulating film TI2 and a third light control layer BM3.

The second insulating film TI2 may be disposed on the second light control layer BM2. The second insulating film TI2 may cover both upper surfaces and side surfaces of the second light control layer BM2, but is not limited thereto.

The second insulating film TI2 may be disposed between the second light control layer BM2 and the third light control layer BM3. The second insulating film TI2 may be disposed between the plurality of patterns PT1, PT2, PT3, and PT4 of the second light control layer BM2 and may fill spaces between the plurality of patterns PT1, PT2, PT3, and PT4 of the second light control layer BM2.

The second insulating film TI2 may include the same material as the first insulating film TI1, but is not limited thereto.

The third light control layer BM3 may be formed of the same material as the first light control layer BM1 and the second light control layer BM2.

The third light control layer BM3 may include a plurality of patterns PT5, PT6, PT7, and PT8. The third light control layer BM3 may include fifth to eighth patterns PT5, PT6, PT7, and PT8.

Each of the fifth to eighth patterns PT5, PT6, PT7, and PT8 may be disposed on each of the first to fourth patterns PT1, PT2, PT3, and PT4.

The shape of each of the fifth to eighth patterns PT5, PT6, PT7, and PT8 may be substantially the same as the shape of each of the first to fourth patterns PT1, PT2, PT3, and PT4, but is not limited thereto. In an example, each of the fifth to eighth patterns PT5, PT6, PT7, and PT8 may be an island physically separated from each other and physically not connected to each other. In an example, each island may extend in the second direction DR2 (or along any direction in which the light control member BM extends).

The third light control layer BM3 may overlap the second light control layer BM2 in the thickness direction (the third direction DR3). Each of the fifth to eighth patterns PT5, PT6, PT7, and PT8 may overlap the respective one of the first to fourth patterns PT1, PT2, PT3, and PT4 in the thickness direction (third direction DR3).

The third light control layer BM3 may overlap the first light control layer BM1 in the thickness direction (the third direction DR3). The third light control layer BM3 may overlap the first light control layer BM1 in the thickness direction (the third direction DR3) across the entire area, but is not limited thereto.

Each of the fifth to eighth patterns PT5, PT6, PT7, and PT8 may have a third width WD3. The third width WD3 of each of the fifth to eighth patterns PT5, PT6, PT7, and PT8 may range from 30 nm to 70 nm or from 150 nm to 300 nm.

Here, the third width WD3 may refer to a minimum width of each pattern PT5, PT6, PT7, or PT8 in the first direction DR1. Accordingly, the width of each of the fifth to eighth patterns PT5, PT6, PT7, and PT8 may range from 30 nm to 70 nm or from 150 nm to 300 nm across the entire area.

For example, the first height h1 of the light control member BM_2 may refer to a height from the upper surface of the encapsulation layer 8 to an upper surface of each pattern PT5, PT6, PT7, or PT8 of the third light control layer BM3.

The fifth to eighth patterns PT5, PT6, PT7, and PT8 may be in direct contact with the color filter layer 9, but are not limited thereto.

A thickness of the second light control layer BM2 in the thickness direction (the third direction DR3) of FIG. 9 according to the present example embodiment may be smaller than that of the second light control layer BM2 of FIG. 6. Accordingly, it is possible to facilitate the patterning of the second light control layer BM2 and the third light control layer BM3, thereby suppressing or preventing an increase in time and cost during the process.

Even in this case, according to the arrangement of the light control member BM_2, color mixing prevention, improvement of color and luminance uniformity according to a viewing angle, luminance reduction prevention, etc. can be possible.

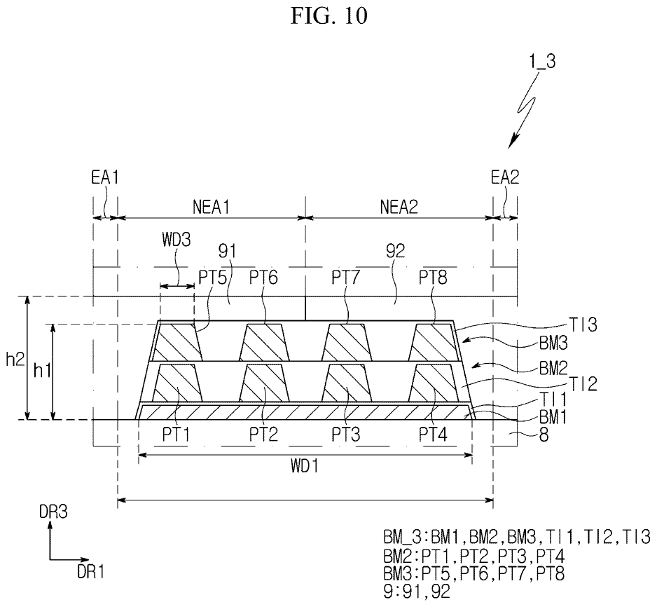

FIG. 10 is an example cross-sectional view of a periphery of a light control member according to yet another example embodiment.

Referring to FIG. 10, a light control member BM_3 of a display apparatus 1_3 according to the present example embodiment may further include a third insulating film TI3 in the configuration of the light control member BM_2 of FIG. 9.

The third insulating film TI3 may be disposed on the third light control layer BM3. The third insulating film TI3 may cover both upper surfaces and side surfaces of the third light control layer BM3, but is not limited thereto.

The third insulating film TI3 may be disposed between the plurality of patterns PT5, PT6, PT7, and PT8 of the third light control layer BM3 and may fill spaces between the plurality of patterns PT5, PT6, PT7, and PT8 of the third light control layer BM3.

The third insulating film TI3 may include the same material as the first insulating film TI1, but is not limited thereto.

The color filter layer 9 may be disposed on the third insulating film TI3.

In this case, since the third light control layer BM3 may be covered by the third insulating film TI3, the third light control layer BM3 can be protected more smoothly.

Even in this case, according to the arrangement of the light control member BM_3, color mixing prevention, improvement of color and luminance uniformity according to a viewing angle, luminance reduction prevention, etc. can be possible.

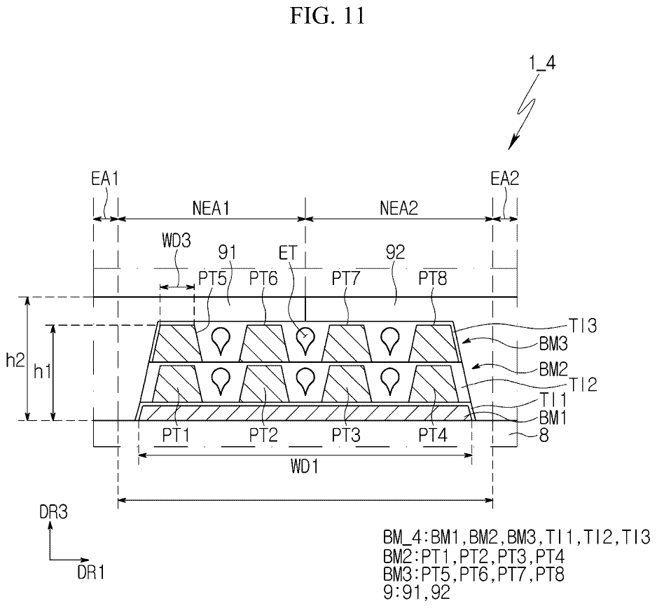

FIG. 11 is an example cross-sectional view of a periphery of a light control member according to yet another example embodiment.

Referring to FIG. 11, a light control member BM_4 of a display apparatus 1_4 according to the present example embodiment may further include an empty space ET defined by the second insulating film TI2 or defined by the third insulating film TI3 in the light control member BM_3 of FIG. 10.

The empty space ET may be surrounded by the second insulating film TI2 or surrounded by the third insulating film TI3. However, the embodiments of the present disclosure are not limited thereto, and the empty space ET may be surrounded by the second insulating film TI2 and the first to fourth patterns PT1, PT2, PT3, and PT4, or surrounded by the third insulating film TI3 and the fifth to eighth patterns PT5, PT6, PT7, and PT8.

The empty space ET may be disposed between the first to fourth patterns PT1, PT2, PT3, and PT4 and/or between the fifth to eighth patterns PT5, PT6, PT7, and PT8. The empty space ET may extend in an extension direction of the light control member BM_4.

Even in this case, according to the arrangement of the light control member BM_4, color mixing prevention, improvement of color and luminance uniformity according to a viewing angle, luminance reduction prevention, etc. can be possible.

Various examples and aspects of the present disclosure are described below. These are provided as examples, and do not limit the scope of the present disclosure.

According to one or more example embodiments of the present disclosure, there is provided a display apparatus including: a substrate; a first light-emitting area, a second light-emitting area, and a third light-emitting area for emitting light of different colors; a light-emitting element disposed on the substrate; an encapsulation layer disposed on the light-emitting element; and a light control member disposed on the encapsulation layer between the first light-emitting area, the second light-emitting area, and the third light-emitting area, in which the light control member includes a first light control layer disposed on the encapsulation layer, a first insulating film disposed on the first light control layer, and a second light control layer disposed on the first insulating film.

In one or more example embodiments of the present disclosure, the first light control layer and the second light control layer may be formed of TiN.

In one or more example embodiments of the present disclosure, a thickness of the first light control layer may range from 90 nm to 120 nm.

In one or more example embodiments of the present disclosure, light reflectivity in a thickness direction of the first light control layer may be 30% or less.

In one or more example embodiments of the present disclosure, the second light control layer may include a plurality of patterns that are disposed sequentially in a first direction, patterned, and separated.

In one or more example embodiments of the present disclosure, the plurality of patterns may include a first pattern disposed at a first end of the plurality of patterns in the first direction, and a second pattern disposed at a second end of the plurality of patterns in the first direction. Each of the first pattern and the second pattern may have a width in the first direction. The width may range from 30 nm to 70 nm or from 150 nm to 300 nm.

In one or more example embodiments of the present disclosure, the light reflectivity of each of the first pattern and the second pattern may be 35% or more.

In one or more example embodiments of the present disclosure, the second light control layer may overlap the first light control layer in the thickness direction.

In one or more example embodiments of the present disclosure, the light control member may further include a second insulating film disposed on the second light control layer, and a third light control layer disposed on the second insulating film.

In one or more example embodiments of the present disclosure, the third light control layer may include a plurality of patterns that are disposed sequentially in the first direction, patterned, and separated. The plurality of patterns may include a first pattern disposed at a first end of the plurality of patterns in the first direction, and a second pattern disposed at a second end of the plurality of patterns in the first direction. Each of the first pattern and the second pattern may have a width in the first direction. The width may range from 30 nm to 70 nm or range from 150 nm to 300 nm.

In one or more example embodiments of the present disclosure, the light control member may further include a third insulating film disposed on the third light control layer.

In one or more example embodiments of the present disclosure, the display apparatus may further include an empty space defined by the third insulating film, in which the empty space may be disposed between the plurality of patterns.

In one or more example embodiments of the present disclosure, the display apparatus may further include an empty space defined by the second insulating film, in which the second light control layer may include a plurality of patterns that are disposed sequentially in the first direction, patterned, and separated, and the empty space may be disposed between the plurality of patterns.

In one or more example embodiments of the present disclosure, the display apparatus may further include a color filter layer disposed on the encapsulation layer, in which the color filter layer may cover the light control member.

In one or more example embodiments of the present disclosure, the color filter layer may include a plurality of color filters that transmit light of different colors, and the light control member may be disposed between the plurality of color filters.

According to one or more example embodiments of the present disclosure, there is provided a display apparatus including a substrate, a light-emitting area for emitting light of different colors and a non-light-emitting area disposed around the light-emitting area, a light-emitting element disposed on the substrate, an encapsulation layer disposed on the light-emitting element, a first light control layer disposed on the encapsulation layer in the non-light-emitting area, and a color filter layer disposed on the encapsulation layer and covering the first light control layer, in which the first light control layer is formed of TiN.

In one or more example embodiments of the present disclosure, a thickness of the first light control layer may range from 90 nm to 120 nm.

In one or more example embodiments of the present disclosure, light reflectivity in a thickness direction of the first light control layer may be 30% or less.

In one or more example embodiments of the present disclosure, the display apparatus may further include a first insulating film disposed on the first light control layer, and a second light control layer disposed on the first insulating film, in which the second light control layer may include a plurality of patterns that are disposed sequentially in the first direction, patterned, and separated.

In one or more example embodiments of the present disclosure, the second light control layer may be formed of TiN. The plurality of patterns may include a first pattern disposed at a first end of the plurality of patterns in the first direction, and a second pattern disposed at a second end of the plurality of patterns in the first direction. Each of the first pattern and the second pattern may have a width in the first direction. The width may range from 30 nm to 70 nm or range from 150 nm to 300 nm.

According to one or more example embodiments of the present disclosure, there is provided a display apparatus including a substrate, a first light-emitting area and a second light-emitting area, a trench area having a trench and disposed between the first light-emitting area and the second light-emitting area, a light-emitting element disposed on the substrate and at the first light-emitting area, the trench area, and the second light-emitting area, an encapsulation layer disposed on the light-emitting element, and a light control member disposed on the encapsulation layer between the first light-emitting area and the second light-emitting area and at the trench area.

In one or more example embodiments of the present disclosure, the display apparatus may further include a first reflective electrode at the first light-emitting area, a second reflective electrode at the second light-emitting area, and a cathode electrode disposed on the first reflective electrode and the second reflective electrode. A distance between an upper surface of the first reflective electrode and an upper surface of the cathode electrode may be greater than a distance between an upper surface of the second reflective electrode and the upper surface of the cathode electrode.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A display apparatus, comprising:
a substrate;
a first light-emitting area, a second light-emitting area, and a third light-emitting area for emitting light of different colors;
a light-emitting element disposed on the substrate;
an encapsulation layer disposed on the light-emitting element; and
a light control member disposed on the encapsulation layer between the first light-emitting area, the second light-emitting area, and the third light-emitting area,
wherein the light control member includes:
a first light control layer disposed on the encapsulation layer;
a first insulating film disposed on the first light control layer; and
a second light control layer disposed on the first insulating film.

2. The display apparatus of claim 1, wherein the first light control layer and the second light control layer are formed of TiN.

3. The display apparatus of claim 1, wherein a thickness of the first light control layer ranges from 90 nm to 120 nm.

4. The display apparatus of claim 1, wherein light reflectivity in a thickness direction of the first light control layer is 30% or less.

5. The display apparatus of claim 1, wherein the second light control layer includes a plurality of patterns that are disposed sequentially in a first direction, patterned, and separated.

6. The display apparatus of claim 5, wherein:
the plurality of patterns comprise: a first pattern disposed at a first end of the plurality of patterns in the first direction; and a second pattern disposed at a second end of the plurality of patterns in the first direction;
each of the first pattern and the second pattern has a width in the first direction; and
the width ranges from 30 nm to 70 nm or from 150 nm to 300 nm.

7. The display apparatus of claim 6, wherein light reflectivity of each of the first pattern and the second pattern is 35% or more.

8. The display apparatus of claim 1, wherein the second light control layer overlaps the first light control layer in a thickness direction.

9. The display apparatus of claim 1, wherein the light control member further includes a second insulating film disposed on the second light control layer, and a third light control layer disposed on the second insulating film.

10. The display apparatus of claim 9, wherein:
the third light control layer includes a plurality of patterns that are disposed sequentially in a first direction, patterned, and separated;
the plurality of patterns comprise: a first pattern disposed at a first end of the plurality of patterns in the first direction; and a second pattern disposed at a second end of the plurality of patterns in the first direction;
each of the first pattern and the second pattern has a width in the first direction; and
the width ranges from 30 nm to 70 nm or range from 150 nm to 300 nm.

11. The display apparatus of claim 10, wherein the light control member further includes a third insulating film disposed on the third light control layer.

12. The display apparatus of claim 11, further comprising an empty space defined by the third insulating film,
wherein the empty space is disposed between the plurality of patterns.

13. The display apparatus of claim 9, further comprising an empty space defined by the second insulating film,
wherein the second light control layer includes a plurality of patterns that are disposed sequentially in a first direction, patterned, and separated, and
wherein the empty space is disposed between the plurality of patterns.

14. The display apparatus of claim 1, further comprising a color filter layer disposed on the encapsulation layer,
wherein the color filter layer covers the light control member.

15. The display apparatus of claim 14, wherein the color filter layer includes a plurality of color filters configured to transmit light of different colors, and
wherein the light control member is disposed between the plurality of color filters.

16. A display apparatus, comprising:
a substrate;
a light-emitting area for emitting light of different colors and a non-light-emitting area disposed around the light-emitting area;
a light-emitting element disposed on the substrate;
an encapsulation layer disposed on the light-emitting element;
a first light control layer disposed on the encapsulation layer in the non-light-emitting area; and
a color filter layer disposed on the encapsulation layer and covering the first light control layer,
wherein the first light control layer is formed of TiN.

17. The display apparatus of claim 16, wherein a thickness of the first light control layer ranges from 90 nm to 120 nm.

18. The display apparatus of claim 17, wherein light reflectivity in a thickness direction of the first light control layer is 30% or less.

19. The display apparatus of claim 16, further comprising a first insulating film disposed on the first light control layer, and a second light control layer disposed on the first insulating film,
wherein the second light control layer includes a plurality of patterns that are disposed sequentially in a first direction, patterned, and separated.

20. The display apparatus of claim 19, wherein:
the second light control layer is formed of TiN;
the plurality of patterns comprise: a first pattern disposed at a first end of the plurality of patterns in the first direction; and a second pattern disposed at a second end of the plurality of patterns in the first direction;
each of the first pattern and the second pattern has a width in the first direction; and
the width ranges from 30 nm to 70 nm or ranges from 150 nm to 300 nm.

21. A display apparatus, comprising:
a substrate;
a first light-emitting area and a second light-emitting area;
a trench area having a trench and disposed between the first light-emitting area and the second light-emitting area;
a light-emitting element disposed on the substrate and at the first light-emitting area, the trench area, and the second light-emitting area;
an encapsulation layer disposed on the light-emitting element; and
a light control member disposed on the encapsulation layer between the first light-emitting area and the second light-emitting area and at the trench area.

22. The display apparatus of claim 21, further comprising:
a first reflective electrode at the first light-emitting area;
a second reflective electrode at the second light-emitting area; and
a cathode electrode disposed on the first reflective electrode and the second reflective electrode,
wherein a distance between an upper surface of the first reflective electrode and an upper surface of the cathode electrode is greater than a distance between an upper surface of the second reflective electrode and the upper surface of the cathode electrode.
